(19) United States
(12) Patent Application Publication
(10) Pub. No.: US 2008/0315902 A1
(43) Pub. Date: Dec. 25, 2008

(54) TEST DEVICE, TEST CARD, AND TEST SYSTEM

(75) Inventor: Hideo KOBAYASHI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/131,362

(22) Filed: Jun. 2, 2008

(30) Foreign Application Priority Data
Jun. 20, 2007 (JP) 2007-161971

(51) Int. Cl. G01R 31/02

(52) U.S. Cl. 324/755

(57) ABSTRACT

A test device to be connected to a multi-card slot of an electronic apparatus performs test for connection between a card inserted into the multi-card slot and the multi-card slot with a plurality of connection terminals. The test device includes a test card and a connection unit. The test card includes a plurality of contact portions to be connected to all of the plurality of connection terminals of the multi-card slot and is inserted into the multi-card slot. The connection unit includes the plurality of cards and connects the plurality of cards to the test card.

### BACKGROUND OF THE INVENTION

1. Field of the Invention

The present invention relates to a test device, a test card, and a test system which are applied to electronic apparatuses with a multi-card slot capable of accepting a plurality of types of electronic cards.

2. Description of the Related Art

The number of electronic apparatuses with a multi-card slot capable of accepting a plurality of types of electronic cards such as flash memory cards is increasing. In addition, the number of types of cards adaptable to such electronic apparatuses is increasing. In such electronic apparatuses, a continuity and function test is performed for cards supported by the electronic apparatus. In the continuity and function test, the insertion and removal of a card are manually performed a plurality of times.

FIGS. 1A and 1B are diagrams describing a method of testing cards using a multi-card slot in the related art. FIG. 1A is a diagram describing a multi-card slot and cards. (1) A tester inserts a card A supported by an electronic apparatus into a multi-card slot 101 of the electronic apparatus so as to perform a test for the card. (2) When the test is completed, the tester removes the card A from the multi-card slot 101. (3) Subsequently, the tester inserts a card B supported by the electronic apparatus into the multi-card slot 101 of the electronic apparatus so as to perform a test for the card. (4) When the test is completed, the tester removes the card B from the multi-card slot 101. (5) Subsequently, the tester inserts a card C supported by the electronic apparatus into the multi-card slot 101 of the electronic apparatus so as to perform a test for the card. (6) When the test is completed, the tester removes the card C from the multi-card slot 101.

Thus, the tester inserts and removes all the cards into and from the multi-card slot 101 one by one when testing the multi-card slot 101. FIG. 1B is a diagram describing connection terminals of a multi-card slot and cards. The electronic apparatus includes the multi-card slot 101, a card controller 102, a system bus 103, and a CPU 104. The multi-card slot 101 includes connection terminals 110, 111, and 112 used for connections to the cards B, C, and A, respectively, which are inserted thereinto. The card A, B, or C is inserted into the multi-card slot 101 and is then connected to the connection terminal 110, 111, or 112. Subsequently, the CPU 104 communicates with the card A, B, or C via the card controller 102. Thus, signal lines and circuit functions which are used by the cards A, B, and C are different from each other. Accordingly, in order to test all circuits used for connections between the electronic apparatus and the cards A, B, and C, it is required to replace the different types of cards A, B, and C one by one.

In order to test a multi-card slot of an electronic apparatus using cards, it is required to perform the continuity and function test for each of the cards. In order to perform the continuity and function test for each of the cards, it is required to insert and remove the cards into and from the electronic apparatus one by one. Accordingly, a person must monitor the completion of the continuity and function test for each of the cards and perform the insertion and removal of each of the cards. This reduces working efficiency.

### SUMMARY

It is an object of the present invention to provide a test device with which a test for the connection between each of a plurality of types of cards and an electronic apparatus is performed by inserting a test card corresponding to the cards into the multi-card slot of the electronic apparatus.

A test device to be connected to a multi-card slot of an electronic apparatus performs test for connection between a card inserted into the multi-card slot and the multi-card slot with a plurality of connection terminals. The test device includes a test card and a connection unit. The test card includes a plurality of contact portions to be connected to all of the plurality of connection terminals of the multi-card slot and is inserted into the multi-card slot. The connection unit includes the plurality of cards and connects the plurality of cards to the test card.

### BRIEF DESCRIPTION OF THE DRAWINGS

FIGS. 1A and 1B are diagrams describing a method of testing cards using a multi-card slot in the related art;

FIG. 2 is a first diagram illustrating a configuration of a multi-card slot test system;

FIG. 3 is a diagram illustrating a configuration of a test card;

FIG. 4 is a first diagram illustrating a configuration of a switching circuit;

FIGS. 5A and 5B are first diagrams illustrating a structure of a test card;

FIGS. 6A, 6B, and 6C are diagrams describing a test card inserted into a multi-card slot;

FIGS. 7A and 7B are second diagrams illustrating a structure of a test card;

FIG. 8 is a third diagram illustrating a structure of a test card;

FIGS. 9A to 9G are fourth diagrams illustrating a structure of a test card;

FIG. 10 is a diagram describing an operation of a multi-card slot test system;

FIG. 11 is a second diagram illustrating a configuration of a multi-card slot test system;

FIG. 12 is a second diagram illustrating a configuration of a switching circuit;

FIG. 13 is a diagram describing an operation of a switching instruction detection circuit;

FIG. 14 is a third diagram illustrating a configuration of a multi-card slot test system;

FIG. 15 is a fourth diagram illustrating a configuration of a multi-card slot test system; and

FIG. 16 is a fifth diagram illustrating a configuration of a multi-card slot test system.

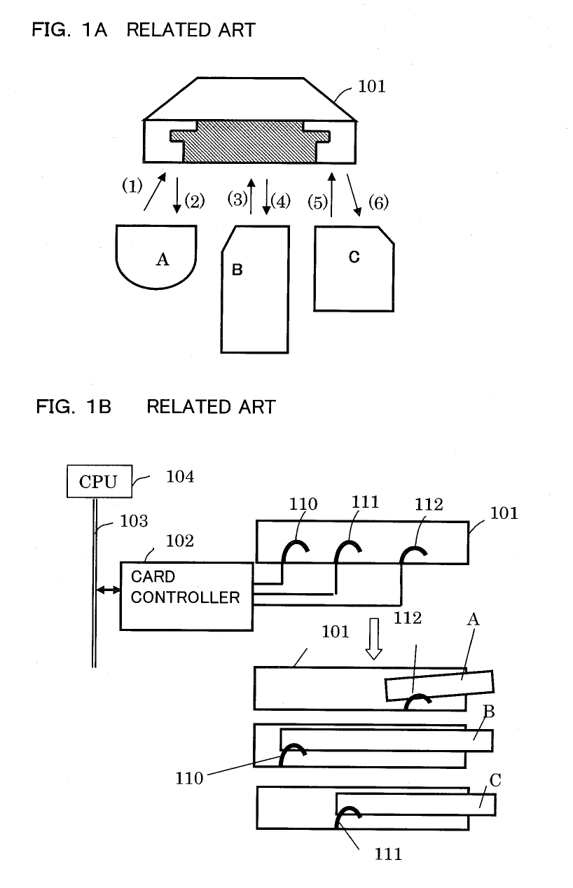

### DESCRIPTION OF THE PREFERRED EMBODIMENTS

### First Embodiment

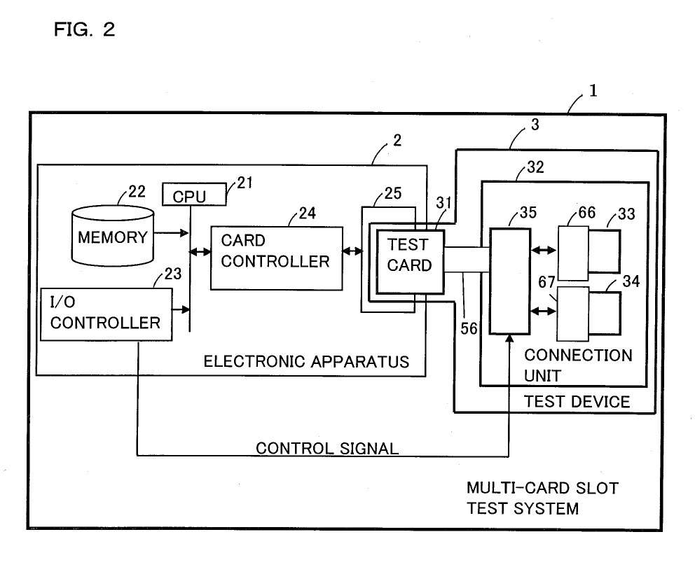

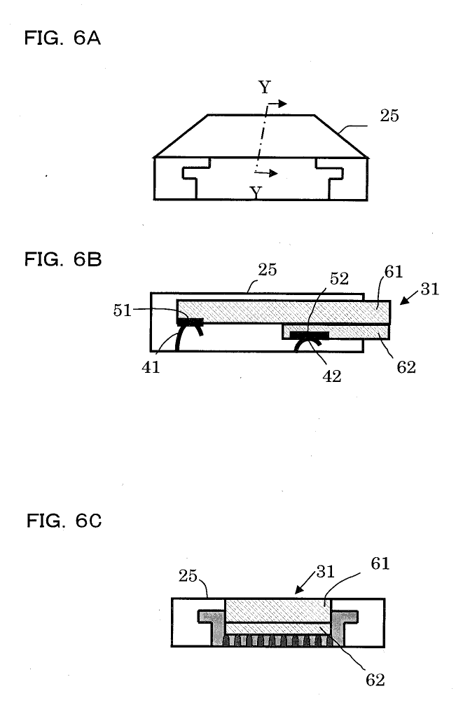

FIG. 2 is a first diagram illustrating a configuration of a multi-card slot test system. A multi-card slot test system 1 includes an electronic apparatus 2 and a test device 3. The electronic apparatus 2 includes a CPU 21, a memory 22, an I/O controller 23, a card controller 24, and a multi-card slot 25. Here, an exemplary case in which two types of cards A33 and B34 are connected to the multi-card slot 25 will be described. However, another type of card may be connected to the multi-card slot 25 using the same configuration. The CPU 21 is a controller for controlling the entire operation of the electronic apparatus 2 using a program included in the memory 22. The CPU 21 tests the connection between the multi-card slot 25 and the card A33 or B34 using the test device 3 in accordance with a test program included in the memory 22. The memory 22 stores various programs and test result data. The I/O controller 23 transmits an instruction for selecting one of the card A33 and the card B34 to the test device 3. The card controller 24 performs interface control for a plurality of cards (the card A33 and the card B34) inserted into the multi-card slot 25. The multi-card slot 25 is formed by installing a multi-card connector on a substrate, and is then installed in the electronic apparatus 2. The multi-card connector includes a connection terminal 41 and a connection terminal 42 (see FIG. 6) which are used for the connection to a test card 31, the card A33, or the card B34. At the time of performance of a test, the test card 31 is inserted into the multi-card slot 25. At the time of operation of the electronic apparatus 2, the card A33 or the card B34 is inserted into the multi-card slot 25.

The test device 3 includes the test card 31, a connection unit 32, and a cable 56.

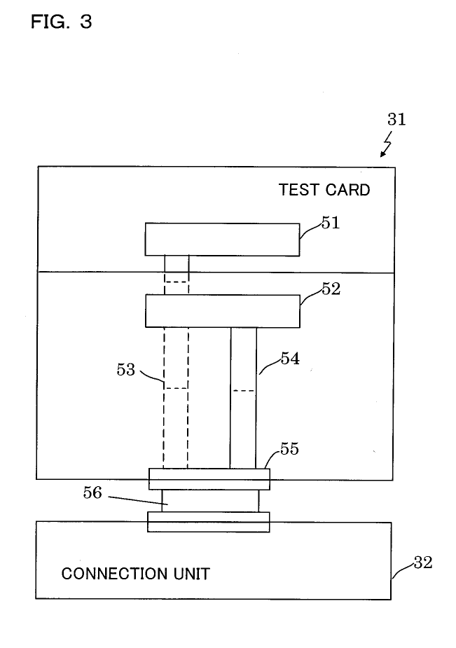

FIG. 3 is a diagram illustrating a configuration of a test card. The test card 31 includes a circuit for connecting the card A33 or the card B34 to the multi-card slot 25. Accordingly, the test card 31 includes an A contact portion 51, a B contact portion 52, a wiring pattern A53, a wiring pattern B54, and a connector 55. The A contact portion 51 is used for the connection to the connection terminal 41 (see FIG. 6) included in the multi-card slot 25. The A contact portion 51 includes a plurality of contact points. The B contact portion 52 is used for the connection to the connection terminal 42 (see FIG. 6) included in the multi-card slot 25. The B contact portion 52 includes a plurality of contact points. The wiring pattern A53 connects the A contact portion 51 to the connector 55. The wiring pattern B54 connects the B contact portion 52 to the connector 55. The connector 55 is used for the connection between the connection unit 32 and the test card 31. The cable 56 connects the connection unit 32 to the test card 31. Referring back to FIG. 2, the connection unit 32 includes the card A33 to be tested, the card B34, a switching circuit 35, a card connector A66, and a card connector B67. The card A33 and the card B34 are different shaped memory cards. The card connector A66 and the card connector B67 are used for the connections to the card A33 and the card B34, respectively. The switching circuit 35 controls the connection between the test card 31 and the card A33 and the connection between the test card 31 and the card B34. Only one of the card A33 and the card B34 is selected and is then connected to the test card 31. The switching circuit 35 is used when a signal for an interface between the electronic apparatus 2 and the card A33 and a signal for an interface between the electronic apparatus 2 and the card B34 are superimposed.

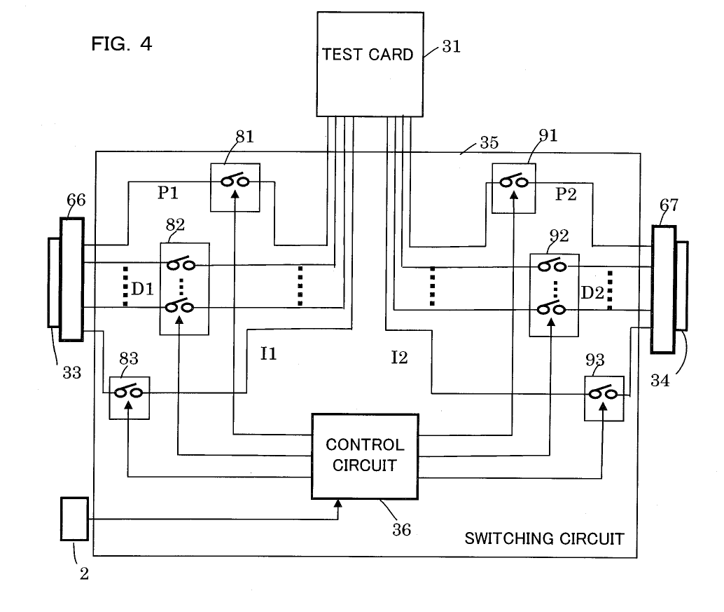

FIG. 4 is a first diagram illustrating a configuration of a switching circuit. The switching circuit 35 includes a control circuit 36, a switching elements 81, 82, 83, 91, 92, and 93. Upon receiving an instruction for connecting the card A33 to the test card 31 from the CPU 21 via the I/O controller 23, the control circuit 36 drives the switching elements 81, 82, and 83 so as to connect the card A33 to the test card 31. Upon receiving an instruction for connecting the card B34 to the test card 31 from the CPU 21 via the I/O controller 23, the control circuit 36 drives the switching elements 91, 92, and 93 so as to connect the card B34 to the test card 31. The switching element 81 is used to transmit a power supply signal P1 from the card A33 to the test card 31. The switching element 91 is used to transmit a power supply signal P2 from the card B34 to the test card 31. The switching element 82 is used to transmit a command signal D1 and data from the card A33 to the test card 31. The switching element 92 is used to transmit a command signal D2 and data from the card B34 to the test card 31. The switching element 83 is used to connect an insertion detection signal line I1 between the card A33 and the test card 31. The switching element 93 is used to connect an insertion detection signal line I2 between the card B34 and the test card 31.

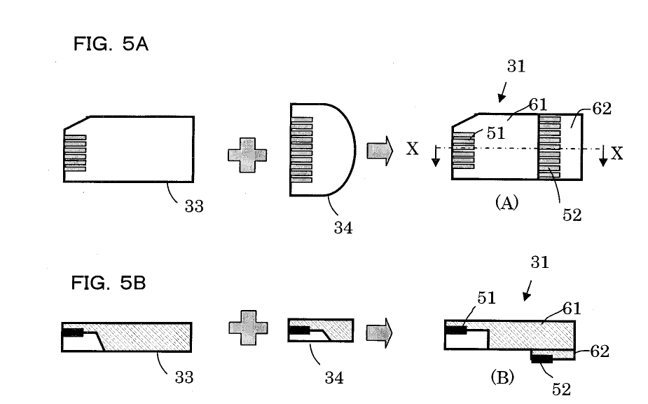

FIGS. 5A and 5B are first diagrams illustrating a structure of a test card.

The test card 31 is configured so that it can be in intimate contact with the connection terminal 41 and the connection terminal 42 (see FIG. 6) which are included in the multi-card slot 25. As illustrated in a plan view in FIG. 5A and a cross-sectional view in FIG. 5B which is taken along the line X-X of FIG. 5A, for example, the test card 31 has a shape obtained by stacking the card A33 and the card B34 in the multi-card slot 25. That is, the test card 31 has a structure in which a pseudo card A61 corresponding to the card A33 and a pseudo card B62 corresponding to the card B34 are stacked. Accordingly, the A contact portion 51 and the B contact portion 52, which are included in the test card 31, are located so that the A contact portion 51 and the B contact portion 52 can be in contact with the connection terminal 41 and the connection terminal 42 (see FIG. 6), respectively, in the multi-card slot 25.

FIGS. 6A, 6B, and 6C are diagrams describing a test card inserted into a multi-card slot.

FIG. 6A is a perspective view of the multi-card slot 25.

FIG. 6B is a cross-sectional view of the multi-card slot 25 included in the electronic apparatus 2 which is taken along the line Y-Y. FIG. 6C is a front view of the multi-card slot 25 which is taken from the insertion hole of the multi-card slot 25.

The connection terminal 41 and the connection terminal 42, which are included in the multi-card slot 25, are in contact with the A contact portion 51 and the B contact portion 52, respectively, which are included in the test card 31.

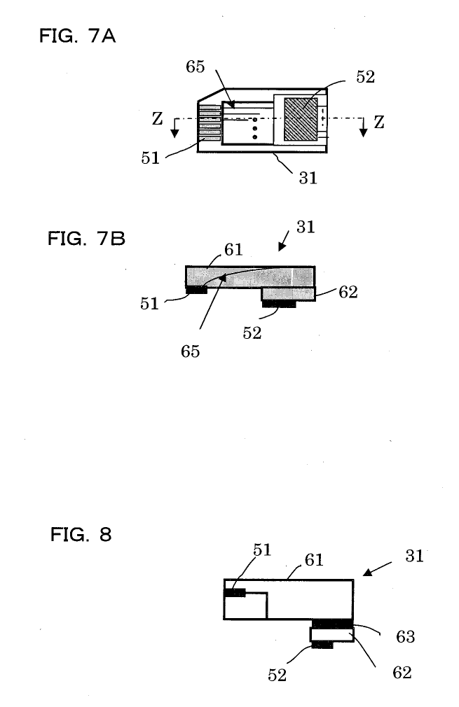

FIGS. 7A and 7B are second diagrams describing a structure of a test card.

FIG. 7A is a plan view of the test card 31. FIG. 7B is a cross-sectional view taken along the line Z-Z.

The A contact portion 51 and the B contact portion 52, which are included in the test card 31, are connected to the connector 55 using the wiring patterns formed on the substrate of the test card 31. However, the A contact portion 51 and the B contact portion 52 may be connected to the connector 55 using a conductor 65. If the conductor 65 is a stranded wire, the quality of a high-speed signal can be improved.

The B contact portion 52 may be formed by an anisotropic conductive film. In this case, the B contact portion 52 can be easily manufactured.

FIG. 8 is a third diagram illustrating a structure of a test card.

The test card 31 is different from the card A33 and the card B34 in shape. Accordingly, when the test card 31 is inserted into the multi-card slot 25, an unnecessary stress may be applied to both of the multi-card slot 25 and the test card 31.

By sandwiching an elastic member 63 between the pseudo card A61 and the pseudo card B62, the unnecessary stress can be relieved. In addition, a contact pressure between the A contact portion 51 included in the test card 31 and the connection terminal 41 included in the multi-card slot 25 and a contact pressure between the B contact portion 52 included in the test card 31 and the connection terminal 42 included in the multi-card slot 25 can be obtained. For example, a rubber member is used as the elastic member 63.

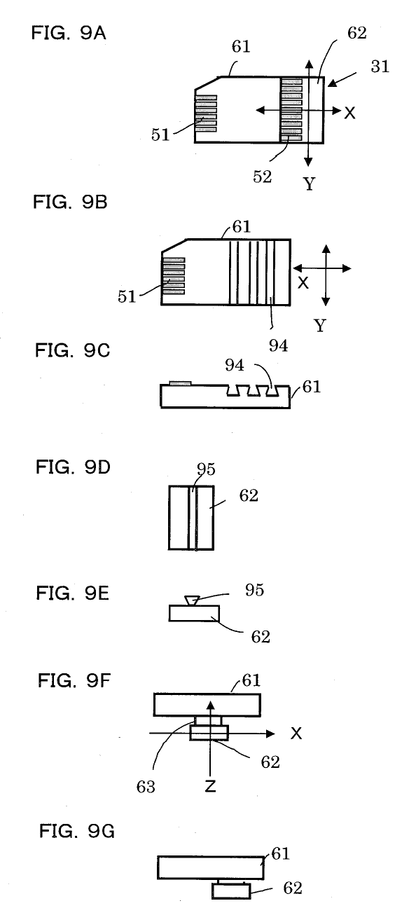

FIG. 9 is a fourth diagram describing a structure of a test card.

By inserting a transfer mechanism allowing a transfer in a particular direction or all directions or a deformable material between the pseudo card A61 and the pseudo card B62, it is possible to use the test card 31 for a plurality of types of different-shaped multi-card slots. As the deformable material, for example, a rubber member can be used.

The description of the transfer mechanism will be made. For example, FIG. 9A illustrates an exemplary case in which the pseudo card B62 included in the test card 31 is transferred in the X and Y directions. FIG. 9B is a diagram describing structures of the pseudo card A61 which allow the transfer of the pseudo card B62 in the X and Y directions. The pseudo card A61 has a plurality of grooves 94 in the Y direction. FIG. 9C is a side view of the pseudo card A61. The grooves 94 prevent the pseudo card B62 from being detached from the test card 31. FIG. 9D is a bottom view of the pseudo card B62. The pseudo card B62 has a rail protrusion 95 for engaging with one of the grooves 94 of the pseudo card A61 on a surface opposite to the mounting surface of the B contact portion 52. FIG. 9E is a side view of the pseudo card B62 illustrated in FIG. 9D. Thus, by changing a position at which the protrusion 95 of the pseudo card B62 engages with one of the grooves 94 of the pseudo card A61, the pseudo card B62 can be transferred in the X direction. Furthermore, by sliding the pseudo card B62 over one of the grooves 94 of the pseudo card A61, the pseudo card B62 can be transferred in the Y direction. FIG. 9F is a side view of the test card 31, and illustrates an exemplary case in which the pseudo card B62 is transferred in the X and Z directions. FIG. 9G illustrates the shape of the test card 31 after the pseudo card B62 has been transferred in the X and Z directions by a predetermined distance.

For example, by inserting an elastic member between the pseudo card A61 and the pseudo card B62, the pseudo card B62 can be transferred in the Z direction.

Thus, the shape of the test card 31 can be changed. Using the above-described structure, the test card 31 can be used for a plurality of different shaped multi-card slots.

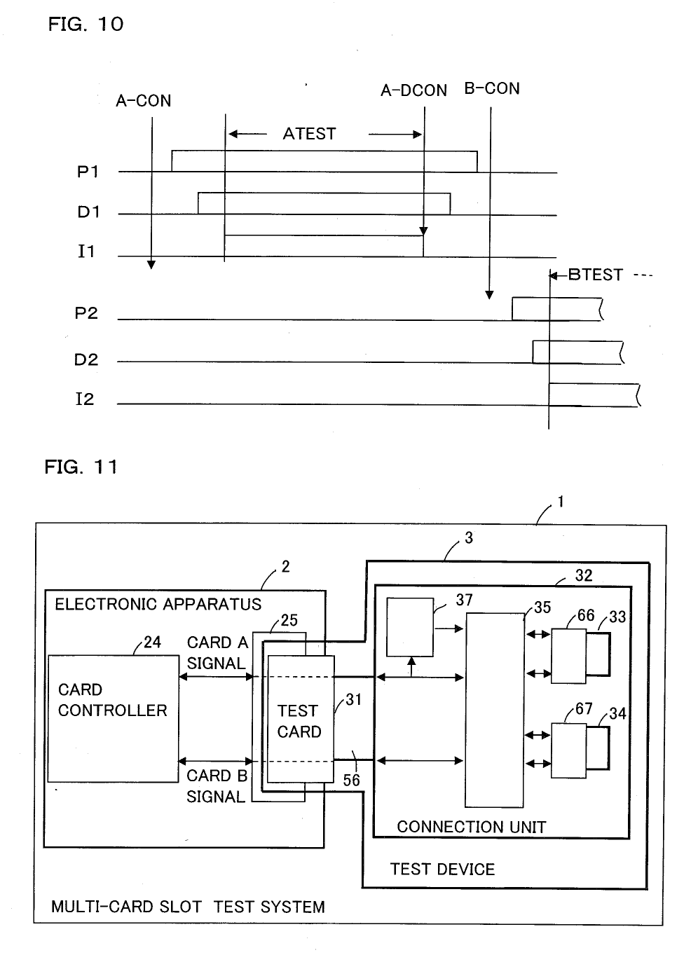

FIG. 10 is a diagram describing an operation of a multi-card slot test system.

A method of testing the card A33 and the card B34 is as follows. First, preparations are made for tests. (1) The card A33 and the card B34 are connected to the card connector A66 and the card connector B67, respectively, in the test device 3. (2) Subsequently, the test card 31 is inserted into the multi-card slot 25 included in the electronic apparatus 2. A tester inputs an instruction for starting a test using a maintenance panel or the like included in the electronic apparatus 2 so as to start the test. (1) Upon detecting the instruction for starting the test, the electronic apparatus 2 transmits an instruction for testing the card A33 to the control circuit 36 included in the test device 3 (A-CON illustrated in FIG. 10). (2) Subsequently, upon receiving the instruction from the electronic apparatus 2, the control circuit 36 included in the test device 3 transmits an instruction for connecting the card A33 to the test card 31 to the switching elements 81, 82, and 83. (3) A power supply line P1, a signal line D1 used for data transfer and command transfer, the insertion detection signal line I1 are sequentially connected between the test card 31 and the card A33. (4) Subsequently, upon detecting via the test card 31 the connection of the insertion detection signal line I1 to the card A33, the electronic apparatus 2 starts the test for the card A33 (A-TEST illustrated in FIG. 10).

In the test, for example, data writing and data reading are performed upon the card to be tested in compliance with the interface standard of the card, and a reading result and a writing result are compared with each other. If the reading result and the writing result are the same, it is determined that the connection between the multi-card slot 25 and the card A33 can be established without any trouble. Subsequently, the result of the test is output to a display unit of the electronic apparatus 2. (5) After the test for the card A33 has been completed, the electronic apparatus 2 transmits an instruction for disconnection of the card A33 to the control circuit 36 (A-DCON illustrated in FIG. 10). (6) The control circuit 36 transmits an instruction for disconnecting the card A33 from the test card 31 to the switching elements 81, 82, and 83. (7) The insertion detection signal line I1, the signal line D1 used for data transfer and command transfer, and the power supply line P1 are sequentially disconnected from the card A33. (8) Subsequently, the electronic apparatus 2 transmits an instruction for testing the card B34 to the test device 3. (9) Upon receiving the instruction from the electronic apparatus 2, the control circuit 36 included in the test device 3 transmits an instruction for connecting the card B34 to the test card 31 to the switching elements 91, 92, and 93 (B-CON illustrated in FIG. 10). (10) The switching elements 91, 92, and 93 connect a power supply line P2, a signal line D2 used for data transfer and command transfer, and the insertion detection signal line I2, respectively, between the test card 31 and the card B34. (11) Subsequently, upon detecting via the test card 31 the connection of the insertion detection signal line I2 to the card B34, the electronic apparatus 2 starts the test for the card B34 (B-TEST illustrated in FIG. 10).

In the test, for example, data writing and data reading are performed upon the card to be tested in compliance with the interface standard of the card, and a writing result and a reading result are compared with each other. If the writing result and the reading result are the same, it is determined that the connection between the multi-card slot 25 and the card B34 can be established without any trouble. Subsequently, the result of the test is output to the display unit or the like included in the electronic apparatus 2. (12) After the test for the card B34 has been completed, the electronic apparatus 2 transmits an instruction for disconnection of the card B34 to the control circuit 36. (13) The control circuit 36 transmits an instruction for disconnecting the card B34 from the test card 31 to the switching elements 91, 92, and 93. (14) The insertion detection signal line I2, the signal line D2 used for data transfer and command transfer, and the power supply line P2 are sequentially disconnected from the card B34.

Thus, all of the tests have been completed.

The configuration of the test device 3 may be changed in accordance with circumstances such as an installation method and the length of a signal line. For example, the test device 3 may be installed on the test card 31.

### Second Embodiment

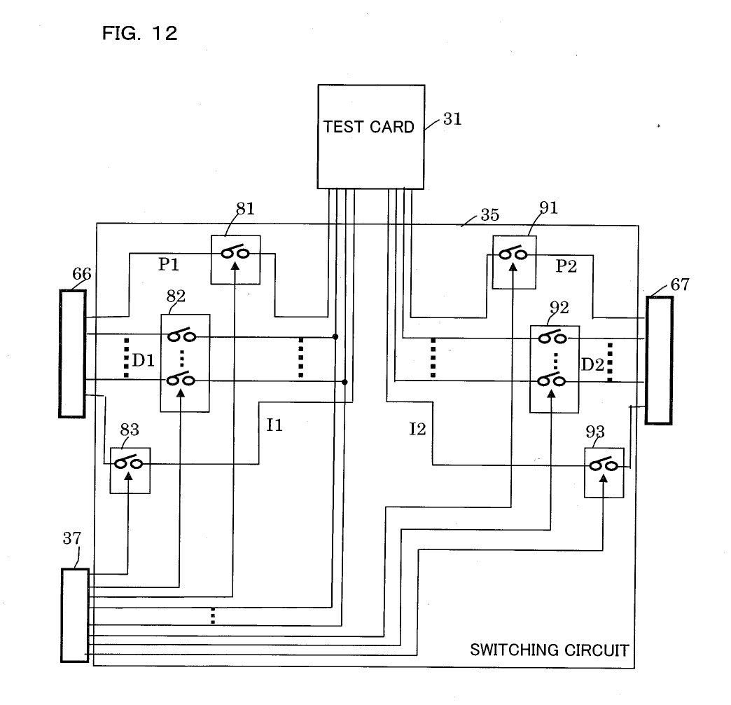

FIG. 11 is a second diagram illustrating a configuration of a multi-card slot test system. This configuration illustrated in FIG. 11 is the same as that illustrated in FIG. 2 except for the configuration of the test device 3. In this drawing, the CPU 21, the memory 22, and the I/O controller 23, which are included in the electronic apparatus 2, are not illustrated. The test device 3 includes the test card 31, the connection unit 32, and the cable 56. The connection unit 32 includes the card A33, the card B34, the switching circuit 35, a switching instruction detection circuit 37, the card connector A66, and the card connector B67. The difference between the first embodiment illustrated in FIG. 2 and the second embodiment is that the switching instruction detection circuit 37 is added to the components illustrated in FIG. 2. FIG. 12 is a second diagram illustrating a configuration of a switching circuit. The difference between the first embodiment illustrated in FIG. 4 and the second embodiment illustrated in FIG. 12 is that the control circuit 36 is not included in the switching circuit 35 in FIG. 12. The switching instruction detection circuit 37 obtains card switching data from the card controller 24, and changes the connection between the card A33 and the test card 31 to the connection between the card B34 and the test card 31.

A method of testing the card A33 and the card B34 is as follows.

First, preparations are made for tests.

In an initial state, the card controller 24 is connected to the card A33. (1) The card A33 and the card B34 are connected to the card connector A66 and the card connector B67, respectively, in the test device 3. (2) Subsequently, the test card 31 is inserted into the multi-card slot 25 included in the electronic apparatus 2.

A tester inputs an instruction for starting a test using a maintenance panel or the like included in the electronic apparatus 2 so as to start the test. (1) Upon detecting via the test card 31 the connection of the insertion detection signal line I1 to the card A33, the electronic apparatus 2 starts the test for the card A33. (2) In the test, for example, test data and card switching data are written into the card A33 in compliance with the interface standard of the card A33. The card switching data includes a switching identification code of the card A33. (3) Subsequently, data reading is performed, and a reading result and a writing result are compared with each other. (4) If the reading result and the writing result are the same, the electronic apparatus 2 determines that the connection between the multi-card slot 25 and the card A33 can be established without any trouble and outputs the result of the test to a display unit included therein. (5) On the other hand, upon detecting the card switching data, the switching instruction detection circuit 37 instructs the switching circuit 35 to change the connection between the card controller 24 and the card A33 to the connection between the card controller 24 and the card B34. (6) Subsequently, upon detecting via the test card 31 the connection of the insertion detection signal line I2 to the card B34 after a certain period of time has elapsed, the electronic apparatus 2 starts the test for the card B34. (7) In the test, for example, test data is written into the card B34 in compliance with the interface standard of the card B34. (8) Subsequently, data reading is performed, and a writing result and a reading result are compared with each other. (9) If the writing result and the reading result are the same, the electronic apparatus 2 determines that the connection between the multi-card slot 25 and the card B34 can be established without any trouble and outputs the result of the test to the display unit included therein.

Thus, all of the tests have been completed.

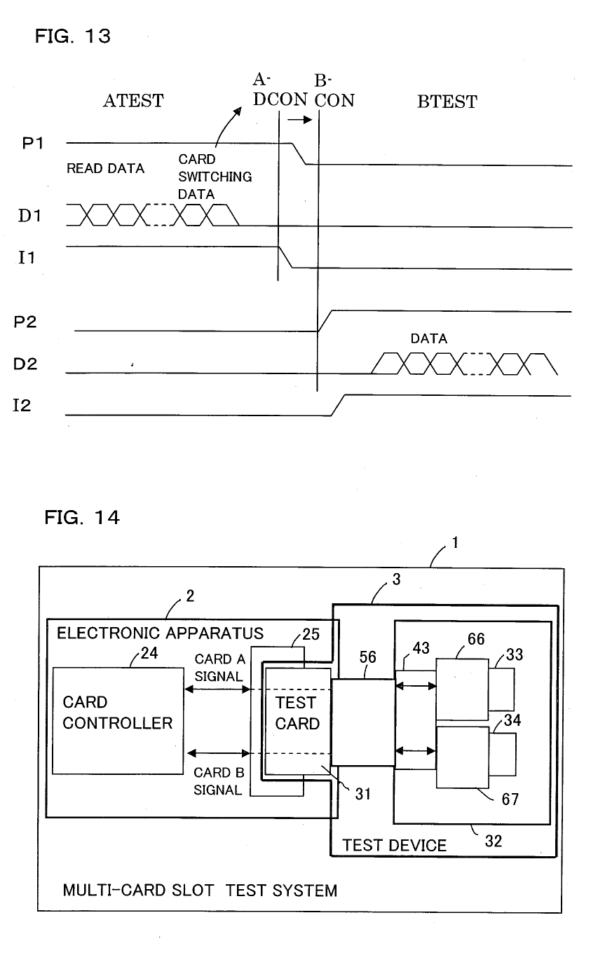

FIG. 13 is a diagram describing an operation of a switching instruction detection circuit.

The switching instruction detection circuit 37 monitors data read from the card A33 during the test for the card A33 (ATEST illustrated in FIG. 13).

Upon detecting the card switching data in the data read from the card A33, the switching instruction detection circuit 37 disconnects the card A33 from the test card 31 after a certain period of time has elapsed (A-DCON illustrated in FIG. 13) so as to change the connection between the card A33 and the test card 31 to the connection between the card B34 and the test card 31 (B-CON illustrated in FIG. 13). Subsequently, the test for the card B34 is performed (BTEST illustrated in FIG. 13).

### Third Embodiment

FIG. 14 is a third diagram illustrating a configuration of a multi-card slot test system. In this configuration, a signal line for the card A33 and a signal line for the card B34 separately exist between the multi-card slot 25 and the card controller 24 in the electronic apparatus 2. The configuration of the test device 3 illustrated in FIG. 14 is different from that of the test device 3 illustrated in FIG. 2. In this drawing, the CPU 21, the memory 22, and the I/O controller 23 are not illustrated in the electronic apparatus 2. The test device 3 includes the test card 31, the connection unit 32, and the cable 56. The connection unit 32 includes the card A33, the card B34, the card connector A66, the card connector B67, and a wiring portion 43. The difference between the first embodiment illustrated in FIG. 2 and the third embodiment illustrated in FIG. 14 is that the switching circuit 35 is not included in FIG. 14. The wiring portion 43 directly transmits signals output from the card A33 and the card B34 to the A contact portion 51 and the B contact portion 52, respectively, without the switching circuit 35. The switching circuit 35 is required when the signal line connected between the multi-card slot 25 and the card controller 24 in the electronic apparatus 2 is shared by the card A33 and the card B34. However, the switching circuit 35 is not required when the signal line for the card A33 and the signal line for the card B34 are separately obtained. A method of testing the card A33 and the card B34 is as follows. First, preparations are made for tests. (1) The card A33 and the card B34 are connected to the card connector A66 and the card connector B67, respectively, in the test device 3. (2) Subsequently, the test card 31 is inserted into the multi-card slot 25 included in the electronic apparatus 2.

A tester inputs an instruction for starting a test using a maintenance panel or the like included in the electronic apparatus 2 so as to start the test. (1) The electronic apparatus 2 detects via the test card 31 the connection of the insertion detection signal line I1 to the card A33 and the connection of the insertion detection signal line I2 to the card B34. (2) The electronic apparatus 2 sequentially starts the test for the card A33 and the test for the B34. In each of the tests, for example, data writing and data reading are performed upon the card to be tested in compliance with the interface standard of the card, and a reading result and a writing result are compared with each other. If the reading result and the writing result are the same, it is determined that the connection between the multi-card slot 25 and each of the card A33 and the card B34 can be established without any trouble. Subsequently, the result of the test is output to a display unit of the electronic apparatus 2.

### Fourth Embodiment

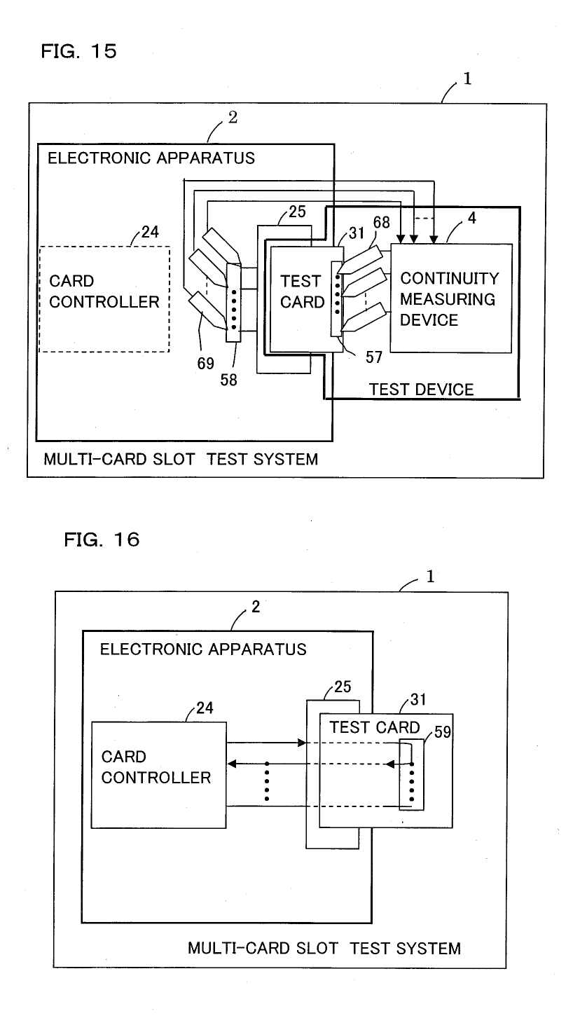

FIG. 15 is a fourth diagram illustrating a configuration of a multi-card slot test system. FIG. 15 illustrates an exemplary case in which only the test for the multi-card slot 25 installed in the electronic apparatus 2 is performed.

In this exemplary case, a test for communication between the test card 31 inserted into the multi-card slot 25 and the multi-card slot 25 is performed. The test device 3 includes the test card 31 and a continuity measuring device 4. The continuity measuring device 4 performs a test for continuity between the test card 31 and the multi-card slot 25. Accordingly, a first signal detection terminal 57 is included in the test card 31, and a second signal detection terminal 58 is included on the substrate of the multi-card slot 25. The continuity measuring device 4 connects a continuity checking probe 68 and a continuity checking probe 69 to the first signal detection terminal 57 and the second signal detection terminal 58, respectively, so as to check the continuity between the test card 31 and the multi-card slot 25. If there is continuity between the test card 31 and the multi-card slot 25, it is determined that the multi-card slot 25 functions normally. Thus, in a case in which the continuity of a signal line is checked, components such as the card A33, the card B34, and the switching circuit 35 can be removed in the test device 3.

### Fifth Embodiment

FIG. 16 is a fifth diagram illustrating a configuration of a multi-card slot test system.

If the card controller 24 has a communication check function such as a boundary scan test, communication check can be performed on the side of the electronic apparatus 2 by folding back a signal line in the test card 31. The test device 3 includes only the test card 31 having a folding back portion 59. The folding back portion 59 receives a signal transmitted from the electronic apparatus 2 via a predetermined contact point in the A contact portion 51 or the B contact portion 52. And the folding back portion 59 transmits the received signal back to the electronic apparatus 2 via another contact point included in the A contact portion 51 or the B contact portion 52.

A test method is as follows. (1) Upon receiving an instruction from the CPU 21, the electronic apparatus 2 sets a communication test mode for the card controller 24. (2) The test is started. (3) The card controller 24 transmits a signal to the test card 31. (4) The signal is transmitted from the test card 31 back to the card controller 24 by the folding back portion 59. (5) The card controller 24 compares the signal transmitted therefrom to the test card 31 with the signal transmitted from the test card 31 back thereto. If the signals are the same, the card controller 24 transmits a normal response to the CPU 21. (6) The CPU 21 outputs the result of the test to a display unit or the like. The folding back portion 59 may be included in the connection unit 32. Another embodiment can be considered in which the connection unit 32 is included in the test card 31. In this case, since the test card 31 and the connection unit 32 are integrated, the cable 56 between the test card 31 and the connection unit 32 can be removed. Furthermore, the usability of test device 3 can be improved when a test is performed. An emulator may be connected to the test card 31 instead of the card A33 and the card B34 so as to check the connection between the electronic apparatus 2 and the test card 31.

What is claimed is:

1. A test device to be connected to a multi-card slot with a plurality of connection terminals of an electronic apparatus, said electronic apparatus performing test for connection between the multi-card slot and a card inserted into the multi-card slot, the test device comprising:
a test card having a plurality of contact portions to be connected to all of the plurality of connection terminals of the multi-card slot and being inserted into the multi-card slot; and
a connection unit for including the plurality of cards and connecting the plurality of cards to the test card.

2. The test device according to claim 1, wherein the connection unit includes,
a connector to be connected to the plurality of cards, and
a switching circuit for selecting one of the plurality of cards connected to the connector as the card to be connected to the test card.

3. The test device according to claim 2, wherein the switching circuit includes,
a control circuit used to select the card to be connected to the test card, and
a switching element used to connect the selected card to the test card.

4. The test device according to claim 1, wherein the connection unit includes,
a connector to be connected to the plurality of cards,
a switching instruction detection portion for detecting card switching data transmitted between the electronic apparatus and one of the plurality of cards, and
a switching circuit for selecting one of the plurality of cards connected to the connector as the card to be connected to the test card on the basis of the detected card switching data.

5. The test device according to claim 1, wherein the connection unit includes,
a connector to be connected to the plurality of cards, and
a wiring portion for directly transmitting a signal output from each of the plurality of cards connected to the connector to the test card.

6. The test device according to claim 1, wherein the test card includes a transfer mechanism used to move the plurality of contact portions.

7. The test device according to claim 1, wherein the test card has a structure in which the plurality of cards are stacked and an elastic member is disposed between the plurality of cards.

8. A test card to be connected to a multi-card slot with a plurality of connection terminals of an electronic apparatus, said electronic apparatus performing test for connection between the multi-card slot and a card inserted into the multi-card slot, the test card comprising:
a plurality of contact portions to be connected to all of the plurality of connection terminals of the multi-card slot; and
a folding back portion for receiving a signal transmitted from the electronic apparatus via the contact portions and transmitting the received signal back to the electronic apparatus via the contact portions.

9. A test system comprising:
an electronic apparatus performing test for connection between a multi-card slot and a card inserted into the multi-card slot;
a test card having a plurality of contact portions to be connected to all of the plurality of connection terminals of the multi-card slot and being inserted into the multi-card slot; and
a connection unit for including the plurality of cards and connecting the plurality of cards to the test card.
